(19) United States
(12) Patent Application Publication
(10) Pub. No.: US 2015/0243833 A1
(43) Pub. Date: Aug. 27, 2015

(54) METHOD FOR PRODUCING THE ELECTRICAL CONTACTS OF A SEMICONDUCTOR DEVICE

(71) Applicant: COMMISSARIAT A L'ENERGIE ATOMIQUE ET AUX ENE ALT, Paris (FR)

(72) Inventors: Thibaut Desrues, Mont Saint Aignan (FR); Sylvain De Vecchi, Chambery (FR); Fabien Ozanne, Allevard (FR); Florent Souche, Saint Laurent Du Pont (FR)

(73) Assignee: COMMISSARIAT A L'ENERGIE ATOMIQUE ET AUX ENE ALT, Paris (FR)

(21) Appl. No.: 14/422,243

(22) PCT Filed: Aug. 22, 2013
(86) PCT No.: PCT/EP2013/067443

§ 371 Date: Feb. 18, 2015

(30) Foreign Application Priority Data
Aug. 23, 2012 (FR) 12 57968

(51) Int. Cl. H01L 31/18; H01L 31/0224

(52) U.S. Cl. CPC H01L 31/1884; H01L 31/022475; H01L 31/022483; H01L 31/022425

(57) ABSTRACT

A method for producing an electrical contact of a semiconductor device, including: depositing an optically transparent electrically conductive layer on a face of the device; depositing first and second dielectric layers on the layer, in which the second dielectric layer can be selectively laser etched; selectively laser etching the second dielectric layer, forming a first opening; producing a second opening aligned with the first opening in the first dielectric layer; depositing an electrically conductive material on the optically transparent electrically conductive layer through the second opening such that portions of the electrically conductive material are deposited on the second dielectric layer, around the first opening; and etching parts of the second dielectric layer which are not covered with portions of the electrically conductive material.

### TECHNICAL FIELD

The invention relates to a method for producing the electrical contacts of a semiconductor device, that is a method for metallizing this device.

This method is advantageously implemented in order to produce the electrical contacts, or metallizations, of photovoltaic cells.

### STATE OF PRIOR ART

Semiconductor devices such as photovoltaic cells have electrical contacts, or metallizations, used for collecting current and for interconnecting the cells with each other.

When these contacts are produced on the front face of the cells, they can advantageously have the shape of a grid in order to allow light to pass into the cells. To reduce to a minimum the shading of these metallizations without causing resistive losses, the width of the metallizations must be reduced while keeping a high electrical conductivity of the metallizations. This can be achieved by producing metallizations through:
screen-printing a conductive paste;
evaporating or sputtering a metal;
metal electroplating.

Producing metallizations by a low cost wet metal electroplating enables a deposition of electrodes to be produced with a large aspect ratio.

This parameter is equal to the thickness to width ratio of the metal lines forming the metallizations. However, it is interesting to restrict this aspect ratio in order to reduce the shading caused by the metallizations.

Such an electroplating is selective in so far as the deposition is made only on the electrically conductive areas. In this case where the entire surface on which the electrical contacts are made is electrically conductive, an electroplated material is then deposited on this entire surface.

In this case it is necessary to locally mask this surface with an insulating or dielectric material, for example having the shape of a grid, in order to perform the electroplating only in the desired areas.

The masks used in the state of the art can be of resin, opaque, with a thickness between a few hundred nanometres and several microns, and made by screen-printing, inkjet or photolithography. These resin masks are removed after the electroplating. However, this method, inspired by microelectronics, remains expensive to produce the metallizations of photovoltaic cells.

Masks can also be made of a dielectric transparent material (for example silicon nitride —SiN—), and in this case these masks can also be used as an anti-reflection layer for the devices. This material can advantageously be opened using a laser and must therefore not necessarily be removed after electroplating. This limits the cost of producing the metallizations with respect to the use of resin masks.

On some photovoltaic cells, a Transparent Conductive Oxide (TCO) is used as a contact material under the metallizations in order to improve the electrical contact of the metallizations.

On such a TCO, it is possible to use resin masks but it is much more difficult to use masks of transparent dielectric material. Indeed, the dielectric masks and the TCO have similar optical refractive indices (1.8≦n≦2.2), which makes the selective ablation of the mask complicated with respect to the TCO. WO 2011/115206 A1 shows an application of such a method, where the laser opening of the dielectric (here silicon oxide) is not selective with respect to the TCO. The laser opening therefore goes through the dielectric layer and the TCO with a major risk of touching the materials located under the TCO. Yet, a degradation of these materials results in performance loss of the photovoltaic cells.

### DISCLOSURE OF THE INVENTION

The aim of the present invention is to provide a method enabling the electrical contacts of a semiconductor device to be produced, advantageously through electroplating or electroless plating for example, on an optically transparent electrically conductive layer (TCO) and through a dielectric layer that can be used as an anti-reflection layer for the semiconductor device, and this without degrading the material(s) located under the TCO.

To this end, the present invention provides a method for producing at least one electrical contact of at least one semiconductor device, comprising at least the steps of:
depositing at least one optically transparent electrically conductive layer on at least one face of the semiconductor device;
depositing at least one first dielectric layer on the optically transparent electrically conductive layer, and at least one second dielectric layer on the first dielectric layer, in which the second dielectric layer can be selectively laser etched with respect to the first dielectric layer and to the optically transparent electrically conductive layer;
selectively laser etching the second dielectric layer, forming at least one first opening through the second dielectric layer, part of the first dielectric layer forming a bottom wall of the first opening;
producing at least one second opening aligned with the first opening and going through the first dielectric layer;
depositing at least one electrically conductive material on the optically transparent electrically conductive layer at least through the second opening.

This method therefore uses, to perform the deposition of an electrically conductive material intended to produce the electrical contact(s) of the device, a mask comprising at least two layers of dielectric material. The upper dielectric layer (the second dielectric layer) is selectively laser etched to define the opening(s) corresponding to the location of the electrical contact(s). This etching selectivity of the second dielectric layer with respect to the first dielectric layer and to the optically transparent electrically conductive layer enables a laser etching to be implemented, defining the location of the electrical contact(s) without damaging the optically transparent electrically conductive layer because the laser radiation energy is absorbed by the second dielectric layer. The opening(s) defined by the previous laser etching through the second dielectric layer can subsequently be extended through the first dielectric layer to the extent of reaching the optically transparent electrically conductive layer without having to use a laser, and therefore still without degrading the optically transparent electrically conductive layer.

Producing the second opening may comprise the implementation of a wet etching of the first dielectric layer through the first opening with a stop on the optically transparent electrically conductive layer.

The semiconductor device may be a photovoltaic cell, and said face of the semiconductor device may correspond to a front face of the photovoltaic cell intended to receive a light radiation.

Depositing the electrically conductive material may comprise the implementation of an electroplating.

The optically transparent electrically conductive layer may comprise ITO and/or ZnO.

An absorption coefficient of the material of the second dielectric layer regarding a laser radiation intended to be used to selectively etch the second dielectric layer may be about 10 times higher than that of the material of the first dielectric layer.

The wavelength of the laser used to selectively etch the second dielectric layer may be between about 300 nm and 600 nm.

The first dielectric layer and the second dielectric layer may comprise silicon nitride and/or silicon oxide, and the material of the first dielectric layer may have a lower silicon concentration than that of the material of the second dielectric layer.

Upon depositing the electrically conductive material on the optically transparent electrically conductive layer, portions of the electrically conductive material may be deposited on the second dielectric layer, around the first opening. In this case, the method may further comprise, after depositing the electrically conductive material on the optically transparent electrically conductive layer, a step of etching parts of the second dielectric layer which are not covered with the portions of electrically conductive material.

Alternatively, the method may further comprise, between the step of producing the second opening and the step of depositing the electrically conductive material on the optically transparent electrically conductive layer, a step of etching the second dielectric layer. In this case, parts of the electrically conductive material may be deposited on parts of the first dielectric layer, around the second openings.

### BRIEF DESCRIPTION OF THE DRAWINGS

The present invention will be better understood upon reading the description of exemplary embodiments given merely as an indication and in no way limiting with reference to the accompanying drawings in which:

FIGS. 1 to 6 depict the steps of a method for producing the electrical contacts of a semiconductor device, object of the present invention, according to a first embodiment;

FIGS. 7 and 8 depict part of the steps of a method for producing the electrical contacts of a semiconductor device, object of the present invention, according to a second embodiment.

Identical, similar or equivalent parts of the different figures described thereafter bear the same reference numerals in order to facilitate switching from one figure to the other.

The different parts shown in the figures are not necessarily drawn to a uniform scale, in order to make the figures more legible.

The different possibilities (alternatives and embodiments) must be understood as being not mutually exclusive and can be mutually combined.

### DETAILED DISCLOSURE OF PARTICULAR EMBODIMENTS

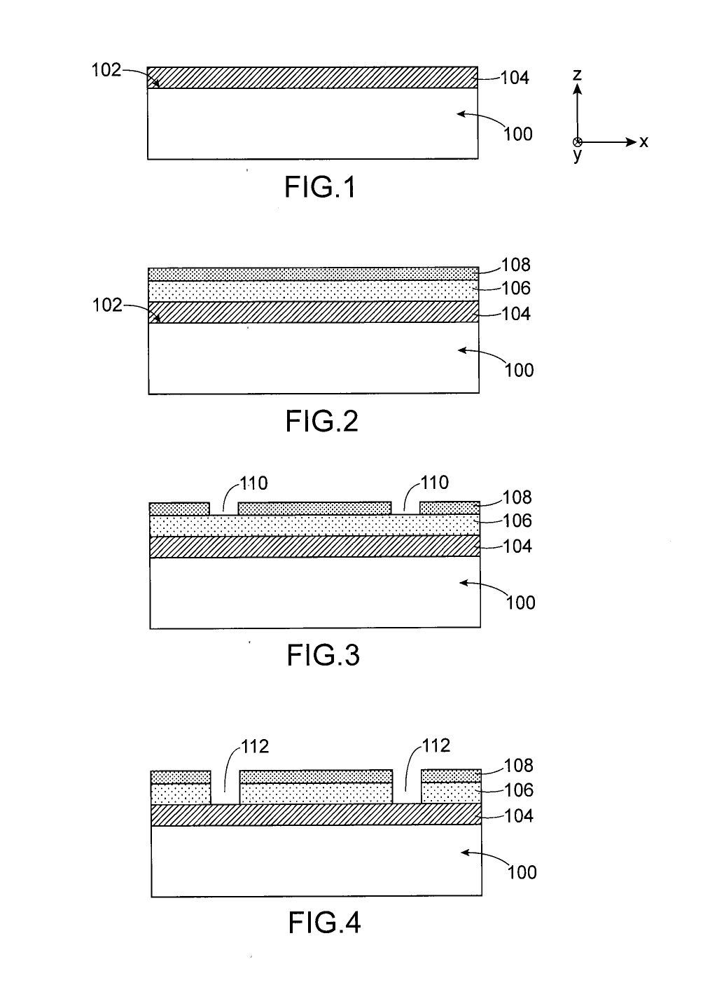

FIGS. 1 to 6 are first referred to, which depict the steps of a method for producing the electrical contacts of a semiconductor device 100 according to a first embodiment.

The semiconductor device 100 is here a photovoltaic cell which, in FIGS. 1 to 6, is schematically shown for the sake of simplification, as a single layer of material. This photovoltaic cell 100 can be any type (homojunction, heterojunction, multijunction, made of amorphous, single-crystal, polycrystalline silicon, etc.). In the first embodiment described here, the photovoltaic cell 100 comprises a front face 102 intended to receive the light radiations from which a photovoltaic conversion will be carried out by the cell 100. At least part of the electrical contacts intended to perform the collection of the current obtained via this photovoltaic conversion of the received light is intended to be produced at this front face 102.

As shown in FIG. 1, depositing an optically transparent electrically conductive layer 104 is first performed on the front face 102 of the photovoltaic cell 100.

This layer 104 is electrically conductive because it is intended to form an electrical contact material for the metallizations, or electrical contacts, intended to be produced at the front face of the cell 100. Moreover, the layer 104 is optically transparent because the light intended to be converted into electricity by the cell 100 must be able to go through this layer 104 and reach the semiconductor junction(s) of the cell 100.

This layer 104 is here made so as to present:
an absorption coefficient k₁ equal to or lower than about 0.1 for wavelengths between about 300 nm and 1200 nm,
a refractive index n₁ between about 1.7 and 2.5 at a wavelength of about 633 nm, and
an electrical conductivity σₗ equal to or greater than about 1.10⁻² S·cm⁻¹.

To achieve these properties, the layer 104 comprises at least one transparent conductive oxide (TCO) such as ITO (Indium Tin Oxide) and/or ZnO, and has a thickness (dimension along the axis Z shown in FIG. 1) between about 10 nm and 100 nm. In this first embodiment, the layer 104 comprises ITO and has a thickness between about 80 nm and 90 nm.

Furthermore, the layer 104 is preferably deposited on the front face 102 through a depositing method involving a depositing temperature equal to or lower than about 200° C. so as not to degrade the material(s) present upon depositing this layer 104, for example through sputtering, that is the materials of the cell 100.

A first dielectric layer 106 and a second dielectric layer 108 are subsequently deposited on the layer 104. The first dielectric layer 106 is intended to be used as an anti-reflection layer for the cell 100. Moreover, both dielectric layers 106 and 108 will be used in mutual cooperation to form a deposition mask used for depositing the electrical contacts at the front face of the cell 100.

The first dielectric layer 106 is here made so as to present:
an absorption coefficient k₂ equal to or lower than about 0.1 for wavelengths between about 300 nm and 1200 nm,
a refractive index n₂ between about 1.7 and 2.5 at a wavelength of about 633 nm,
an electrical conductivity σ₂ equal to or lower than about 1.10⁻¹⁰ S·cm⁻¹.

To achieve these properties, the first dielectric layer 106 here comprises silicon nitride or silicon oxide with a low silicon concentration, for example the silicon of which represents less than about 30% of its composition. The first dielectric layer 106 also has a thickness between about 10 nm and 100 nm, and for example equal to about 100 nm in this first embodiment.

The second dielectric layer 108 is made so as to present an absorption coefficient to a laser radiation greater than that of the first underlying dielectric layer 106 (which can be transparent to this laser radiation), advantageously such as k₃≧10·k₂ for wavelengths between about 300 nm and 600 nm, and particularly for the wavelength of the laser which will be subsequently used to etch the second dielectric layer 108. This absorption coefficient k₃ is also chosen equal to or greater than about 0.1 for wavelengths equal to or lower than about 650 nm.

In this first embodiment, the second dielectric layer 108 comprises silicon nitride or silicon oxide with a strong silicon concentration, for example the silicon of which represents more than about 30% of its composition. The second dielectric layer 108 further has a thickness between about 10 nm and 100 nm, this thickness being equal to about 50 nm in this first embodiment.

The first dielectric layer 106 and the second dielectric layer 108 are preferably deposited on the layer 104 through a depositing method involving a depositing temperature equal to or lower than about 200° C., for example through chemical vapour depositions (CVD) or physical vapour depositions (PVD), which enables material being under the layers 106 and 108 (materials of the layer 104 and of the device 100) not to be degraded.

As shown in FIG. 3, first openings 110 are then made through the second dielectric layer 108 by laser irradiation of parts of the surface of the layer 108. This laser etching is for example implemented such that the wavelength of the laser used is lower than about 600 nm (and for example between about 300 nm and 600 nm), such that the fluence of the laser is between about 0.01 and 10 J/cm², such that the frequency of the laser is between about 10 and 1000 kHz, and that the pitch of the laser is between about 1 and 100 μm.

The pattern of the openings 110 produced through the second dielectric layer 108 corresponds to that of the electrical contacts intended to be produced at the front face of the cell 100.

Given the optical parameters of the layers 104, 106 and 108 previously set out, the second dielectric layer 108 can be selectively etched, during this laser etching step, with respect to the first dielectric layer 106 and to the layer 104. This etching selectivity is especially achieved thanks to the fact that the absorption coefficient k₃ of the second dielectric layer 108 is greater than those of the layers 104 and 106 for the wavelength of the laser used.

As shown in FIG. 4, second openings 112 are then produced through the first dielectric layer 106. These second openings 112 are made in the extension of the first openings 110. These second openings 112 are achieved through a selective etching, corresponding for example to a wet etching implemented with an HF (hydrofluoric acid) type solution, of parts of the first dielectric layer 106 with respect to the second dielectric layer 108 and to the layer 104. In this exemplary embodiment, this solution has a concentration of HF elements equal to about 2%, and etching is carried out for a period equal to about 10 minutes.

This etching selectivity of the material of the first dielectric layer 106 with respect to the second dielectric layer 108 and to the layer 104 is achieved due to the nature of the material of the first dielectric layer 106, here being low in silicon, which has a low optical absorption and is more rapidly etched than the material of the second dielectric layer 108 which is rich in silicon.

As shown in FIG. 5, the remaining parts of the second dielectric layer 108 are subsequently selectively etched with respect to the first dielectric layer 106 and to the layer 104, for example through a wet etching implemented with a KOH (potassium hydroxide) type solution.

This etching is here implemented for a period equal to about 2 minutes. This etching selectivity of the material of the second dielectric layer 108 with respect to the first dielectric layer 106 and to the layer 104 is achieved due to the nature of the material of the second dielectric layer 108, here with a stronger silicon concentration, which has a greater optical absorption and is more rapidly etched than the material of the first dielectric layer 106 with a low silicon concentration.

Metallizations 114 are then produced in the second openings 112, in electrical contact with the parts of the layer 104 forming the bottom walls of the openings 112. The material of the metallizations 114 is such as to present a conductivity σ₃ equal to or greater than about 1.10⁴ S·cm⁻¹ and an etching selectivity regarding the materials of the layer 104 and of the dielectric layers 106 and 108 (the layer 104 and the dielectric layers 106 and 108 therefore also having an etching selectivity regarding the material of the metallizations 114).

The thickness of the metallizations 114 (dimension along the axis Z) is here between about 5 μm and 50 μm.

Furthermore, the metallizations 114 are here achieved through an electroplating of copper, for example implemented at a temperature equal to or lower than about 200° C. Other electrically conductive materials can be used to produce the metallizations 114, such as for example nickel, aluminium, titanium, tungsten, etc. Parts of the metallizations 114 rest on parts of the first dielectric layer 106 on the periphery of the second openings 112.

The steps of a method for producing the electrical contacts of a semiconductor device 100 will now be described according to a second embodiment.

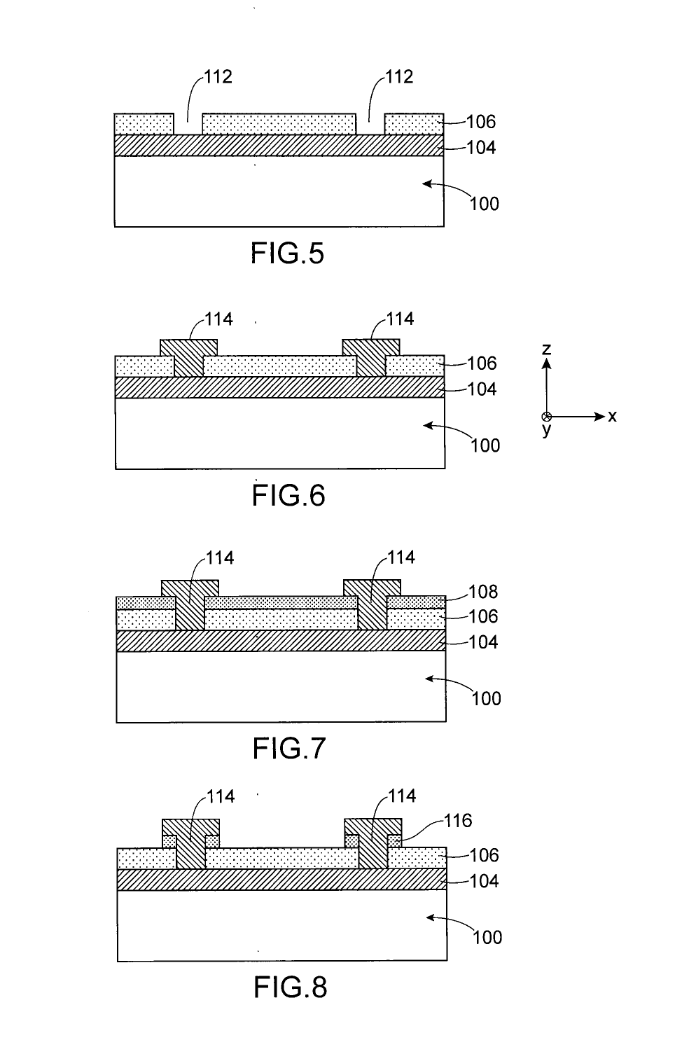

The steps previously described in relation to FIGS. 1 to 4 are first implemented. Subsequently, instead of removing the remaining parts of the second dielectric layer 108 as in the first embodiment, the deposition of the metallizations 114 in the openings 110 and 112 is performed (FIG. 7). Thus, parts of metallizations 114 rest on parts of the second dielectric layer 108 on the periphery of the first openings 110.

As shown in FIG. 8, a second dielectric layer 108 is subsequently etched as previously described for the first embodiment. Because the metallizations 114 have been produced before this etching, parts 116 of the second dielectric layer 108 which are covered by the metallizations 114 are kept after etching the second dielectric layer 108.

1-8. (canceled)

9. A method for producing at least one electrical contact of at least one semiconductor device, comprising:
depositing at least one optically transparent electrically conductive layer on at least one face of the semiconductor device;
depositing at least one first dielectric layer on the optically transparent electrically conductive layer, and at least one second dielectric layer on the first dielectric layer, in which the second dielectric layer can be selectively laser etched with respect to the first dielectric layer and to the optically transparent electrically conductive layer;
selectively laser etching the second dielectric layer, forming at least one first opening through the second dielectric layer, part of the first dielectric layer forming a bottom wall of the first opening;
producing at least one second opening aligned with the first opening and passing through the first dielectric layer;
depositing at least one electrically conductive material on the optically transparent electrically conductive layer at least through the second opening such that portions of the electrically conductive material are deposited on the second dielectric layer, around the first opening;
etching parts of the second dielectric layer which are not covered with portions of the electrically conductive material.

10. The method according to claim 9, wherein the producing the second opening comprises implementing a wet etching of the first dielectric layer through the first opening with a stop on the optically transparent electrically conductive layer.

11. The method according to claim 9, wherein the semiconductor device is a photovoltaic cell, the face of the semiconductor device corresponding to a front face of the photovoltaic cell intended to receive a light radiation.

12. The method according to claim 9, wherein the depositing the electrically conductive material comprises implementing an electroplating.

13. The method according to claim 9, wherein the optically transparent electrically conductive layer comprises at least one of ITO and ZnO.

14. The method according to claim 9, wherein an absorption coefficient of a material of the second dielectric layer regarding a laser radiation intended to be used to selectively etch the second dielectric layer is about 10 times higher than that of a material of the first dielectric layer.

15. The method according to claim 9, wherein a wavelength of the laser used to selectively etch the second dielectric layer is between about 300 nm and 600 nm.

16. The method according to claim 9, wherein the first dielectric layer and the second dielectric layer comprise at least one of silicon nitride and silicon oxide, a material of the first dielectric layer having a lower silicon concentration than that of a material of the second dielectric layer.
